(19) United States
(12) Patent Application Publication
(10) Pub. No.: US 2009/0194236 A1
(43) Pub. Date: Aug. 6, 2009

(54) Plasma processing equipment

(75) Inventors: Kouichi Ono, Shiga (JP); Hiroyuki Kousaka, Aichi (JP); Kiyotaka Ishibashi, Hyogo (JP); Ikuo Sawada, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: KYOTO UNIVERSITY, Kyoto-shi (JP); TOKYO ELETRON LIMITED, Tokyo (JP)

(21) Appl. No.: 11/630,774

(22) PCT Filed: Jun. 20, 2005
(86) PCT No.: PCT/JP05/11273

§ 371 Date: Dec. 26, 2006

(30) Foreign Application Priority Data
Jun. 25, 2004 (JP) 2004-188474

(51) Int. Cl. C23F 1/08; C23C 16/54; B01J 19/08

(52) U.S. Cl. 156/345.41; 118/723 AN; 422/186.29

(57) ABSTRACT

A plurality of concentric ring-shaped slots (300) to (304) are formed in a planar antenna member (3), and the thickness of conductors in the central part is made relatively thin and the thickness of peripheral conductors is made relatively thick, so that a microwave can easily pass through the slots (300) to (304) without being attenuated, and a uniform electric field distribution can be provided and uniform high-density plasma can be generated in a processing space on an average. As a result, an object to be processed can be provided close to the antenna member (3) and the object can be uniformly processed at high speed.

### TECHNICAL FIELD

The present invention relates to a plasma processing device and more particularly, to a plasma processing device in which a microwave is supplied to a planar antenna member to generate plasma to process a semiconductor device and the like.

### BACKGROUND ART

FIG. 9 is a sectional view showing a plasma processing device disclosed in Japanese Patent Publication No. 3136054, and FIG. 10 is a plan view showing a planar antenna member.

Referring to FIG. 9, a plasma processing device 2 comprises a processing vessel 4 formed into a cylindrical shape as a whole. The ceiling part of the processing vessel 4 is open and a quartz plate 8 is provided air-tightly through a sealing member 5, and a processing space S is formed so as to be hermetically sealed in the processing vessel.

A table 10 on which a semiconductor wafer W as an object to be processed is set is housed in the processing vessel 4. The table 10 is supported by a supporting table 12 set on the bottom of the processing vessel 4 through an insulating material 14. A bias voltage having 13.56 MHz, for example is supplied from a biasing high-frequency power supply 20 to the table 10.

A planar antenna member 3 is provided on the quartz plate 8 that seals the upper part of the processing vessel 4. The planar antenna member 3 is constituted as a bottom plate of a radial waveguide box 40 that is a hollow cylindrical vessel having a low height, and mounted on the upper surface of the quartz plate 8. A dielectric material 50 is provided in the upper part of the planar antenna member 3.

The planar antenna member 3 is a copper plate having a diameter of 50 cm and a thickness of 1 mm or less, for example. As shown in FIG. 10, many slits 31 starting from a position outwardly apart from the center by several cm, for example are spirally swirled twice toward its peripheral part gradually in the copper plate. A microwave is supplied from a microwave generator 42 to the center of the planar antenna member 3 through an inner cable 44B of a coaxial waveguide 44, and the slits 31 receiving the microwave form a uniform electric field distribution in the processing space S beneath the slits. In addition, almost one-round radiation element 32 is formed with its ends differentiated from each other in the radius direction as shown in FIG. 10, which is provided to raise antenna efficiency.

In a plasma process such as plasma CVD, etching, oxidizing, nitriding and the like performed by the plasma processing device disclosed in Japanese Patent Publication No. 3136054, it is required that a substrate of large diameter is collectively and uniformly processed at high speed.

In general, it is necessary to raise a plasma density on the semiconductor wafer W in order to speed up the process with the plasma. Since the plasma density becomes low as the distance from the quartz plate 8 is increased in the high-density plasma energized by the microwave, it is required that uniform plasma is formed at a place close to the quartz plate 8 that is in contact with the planar antenna member as much as possible, and the semiconductor wafer W is set there.

However, since the microwave is spread outwardly from the center in the dielectric material 50, an electric field emitted from the slot closer to the center is stronger. Therefore, in the conventional device, the electric field formed in the space between the quartz plate 8 and the plasma boundary is stronger in the center while it tends to be weak in a peripheral part. As a result, the plasma distribution in the vicinity of the quartz plate 8 cannot be uniformly provided. To provide uniform plasma distribution applied to the semiconductor wafer W it is necessary to make a distance “D” between the planar antenna member 3 and the semiconductor wafer W separated by a predetermined distance or more.

However, in order to improve efficiency, it is required that the semiconductor wafer W is provided close to the planar antenna member 3.

### DISCLOSURE OF THE INVENTION

It is an object of the present invention to provide a plasma processing device comprising an antenna member that can process an object to be processed uniformly at high speed even when the object is provided close to the antenna member.

The present invention is characterized by comprising a processing vessel housing a table on which an object to be processed is set, a microwave generator for generating a microwave, a waveguide for guiding the microwave generated by the microwave generator to the process container, and a planar antenna member connected to the waveguide and arranged so as to be opposed to the table, in which the planar antenna member is separated into an inner conductor region and an outer conductor region by a substantially closed loop groove.

According to the present invention, since the inner conductor and the outer conductor are separated by the closed loop groove in the planar antenna member, even when the antenna member becomes thick, the microwave can easily pass without being attenuated, so that a uniform electric field distribution can be provided. As a result, a uniform plasma distribution can be provided over the plane and an object to be processed can be provided close to the antenna member, so that the object can be processed uniformly at high speed.

According to one embodiment, a plurality of the loop grooves are provided and they are concentrically arranged, and more particularly, a plurality of the loop grooves are provided and they are concentrically arranged in the form of rectangles.

Preferably, the loop groove is a slot penetrating the planar antenna member in the thickness direction.

According to another embodiment, the inner conductor and the outer conductor are connected by a connecting member crossing the loop groove. When the inner conductor region and the outer conductor region are connected by the connecting member, the inner conductor region and the outer conductor region can have the same potential, so that unnecessary abnormal discharge is prevented from being generated.

Preferably, the connecting member connects the inner conductor region and the outer conductor region in the loop groove in the height direction.

The planar antenna member comprises an insulating member separated by the loop groove and an electrically conductive member coated on the surface of the insulating member to constitute the inner conductor region and the outer conductor region separated by the loop groove.

Preferably, the planar antenna member has a peripheral part formed to be relatively thick and a central part formed to be relatively thin.

According to one embodiment, the planar antenna member comprises a metal member constituting the inner conductor region and the outer conductor region separated by the loop groove and an insulating member covering the metal member. According to another embodiment, the planar antenna member comprises an insulating member separated by the loop groove and an electrically conductive member coated on the surface of the insulating member to constitute the inner conductor region and the outer conductor region separated by the loop groove.

Preferably, the inner conductor is formed to be relatively thin and the outer conductor is formed to be relatively thick along the loop groove. When the inner conductor is thin and the outer conductor is thick, the electron density in the space under the center of the antenna member can be small and the electron density in the space under the peripheral part of the antenna member can be high, so that the object can be uniformly processed.

Preferably, a cooling path is formed at a part in the peripheral part formed to be thick.

### BRIEF DESCRIPTION OF DRAWINGS

FIG. 1 is a plan view showing an antenna member used in a plasma processing device according to one embodiment of the present invention;

FIG. 2 is a longitudinal sectional view taken along line II-II in FIG. 1;

FIG. 3A is a sectional view showing a radius part of an antenna member in another example used in the plasma processing device according to one embodiment of the present invention;

FIG. 3B is a sectional view showing a radius part of an antenna member in still another example used in the plasma processing device according to one embodiment of the present invention;

FIG. 4A is a sectional view showing a radius part of an antenna member formed thinly as a whole;

FIG. 4B is a sectional view showing a radius part of an antenna member in which a peripheral part is thick and a central part is thin.

FIG. 4C is a sectional view showing a radius part of an antenna member formed thickly as a whole;

FIG. 4D is a sectional view showing a radius part of an antenna member in which a peripheral part is thin and a central part is thick;

FIG. 5A is a view showing an electron density distribution when antenna members 3a to 3d shown in FIGS. 4A to 4D are arranged at Z=70 mm from an antenna surface;

FIG. 5B is a view showing an electron density distribution when the antenna members 3a to 3d shown in FIGS. 4A to 4D are arranged at Z=80 mm from an antenna surface;

FIG. 5C is a view showing an electron density distribution when the antenna members 3a to 3d shown in FIGS. 4A to 4D are arranged at Z=100 mm from an antenna surface;

FIG. 5D is a view showing an electron density distribution when the antenna members 3a to 3d shown in FIGS. 4A to 4D are arranged at Z=150 mm from the antenna surface;

FIG. 6 is a view showing an antenna member according to another example;

FIG. 7A is a plan view showing an example in which conductors of the antenna member are connected by electric conductors;

FIG. 7B is a sectional view taken along line B-B in FIG. 7A and showing the example in which the conductors of the antenna member are connected by the electric conductors;

FIG. 7C is a sectional view showing another example in which conductors of the antenna member are connected by electric conductors;

FIG. 8A is a plan view showing an antenna member;

FIG. 8B is an enlarged sectional view showing a connecting part between slots of the antenna member;

FIG. 8C is an enlarged sectional view showing a connecting part between slots of the antenna member according to another example;

FIG. 9 is a sectional view showing a plasma processing device disclosed in Japanese Patent Publication No. 3136054; and

FIG. 10 is a plan view showing a planar antenna member.

### BEST MODE FOR CARRYING OUT THE INVENTION

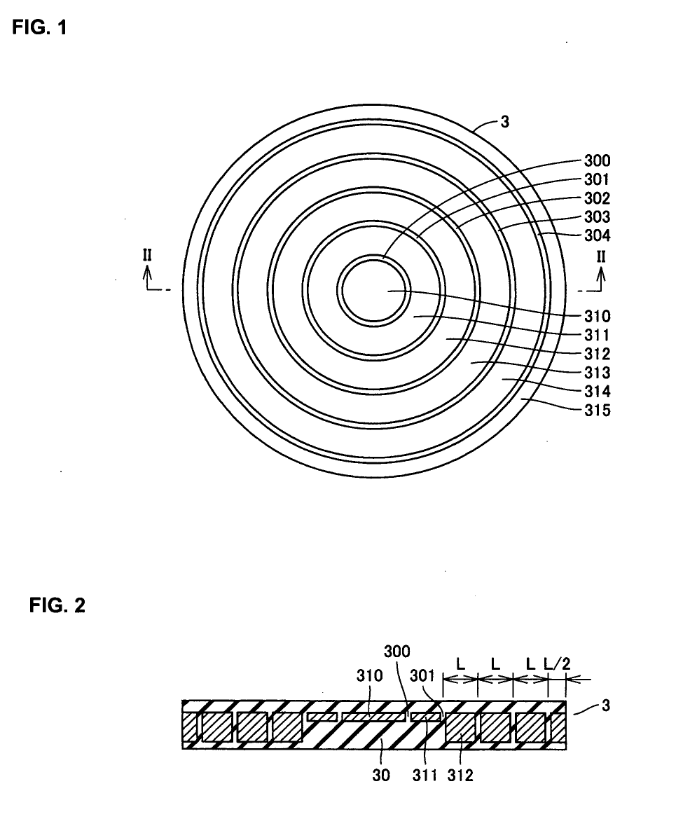

FIG. 1 is a plan view showing an antenna member used in a plasma processing device according to one embodiment of the present invention, and FIG. 2 is a longitudinal sectional view taken along line II-II in FIG. 1.

Referring to FIG. 1, an antenna member 3 is formed of an electrically conductive material such as copper, and slots 300 to 304 are formed as a plurality of concentric and closed grooves in the shape of loops to separate the antenna member 3 into an inner conductor region and an outer conductor region. Each of these slots 300 to 304 penetrates the antenna member 3 from one surface to the other surface in the thickness direction and has a width of 1 mm, for example. A distance “L” between the slots 300, 301, 302 and 303 is set to the integral multiple of a guide wavelength of a microwave and more preferably set to the length of the guide wavelength of the microwave, and the distance between the outermost slot 304 and the outer periphery of the antenna member 3 is set to about L/2. When the distance between the slot 304 and the outer periphery of the antenna member 3 is set to about L/2, the phase of the microwave that reached the outermost slot becomes the same as that of the returned microwave that went through that slot and reflected on a wall (because a round distance is L), so that both microwaves resonate and form a strong electric field.

The antenna member 3 is separated into conductors 310 to 315 by the slots 300 to 304. While the thickness of the conductors 310 and 311 on the center side is relatively thin, that is, 2 mm, for example, the thickness of the peripheral conductors 312 to 315 is relatively thick such as not less than λ/8, more preferably not less than λ/4, that is, 20 mm, for example. When the thickness of the antenna member 3 is varied as described above, since the ends of the slots 302 to 304 formed between the thick conductors 312 to 315 and the plasma can be close to each other, a plasma density can be locally adjusted. Thus, uniformity of the electric field can be improved and a desired plasma distribution can be provided.

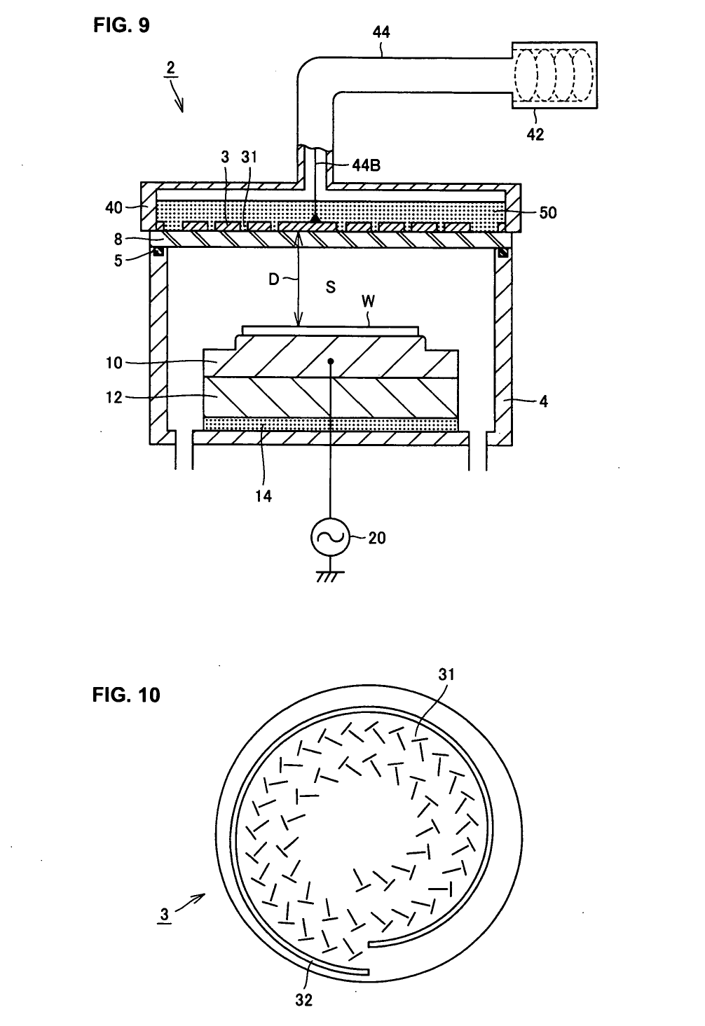

According to a slit 31 shown in FIG. 9 and described above, when the thickness of the antenna member 3 is increased, since the microwave is attenuated and process efficiency deteriorates, it cannot be thick. Meanwhile, according to this embodiment, even when the thickness of the antenna member 3 is increased, since the plurality of slots 300 to 304 are formed, focusing on the slot 301, for example, the conductor 311 becomes an inner conductor and the conductor 312 becomes an outer conductor in the coaxial waveguide, and they serve as a waveguide, so that the microwave can easily pass. As a result, the electric field distribution in a processing space “S” at the lower part of the antenna member 3 can become uniform. In addition, although the plurality of slots 300 to 304 are concentrically formed in FIG. 1, only one slot may be formed.

In addition, when the thickness of the peripheral conductors 312 to 314 is increased, an additional effect can be provided such that the temperature of the slots 300 to 304 themselves and the antenna member 3 can be controlled by forming a cooling path for flowing a refrigerant at that part.

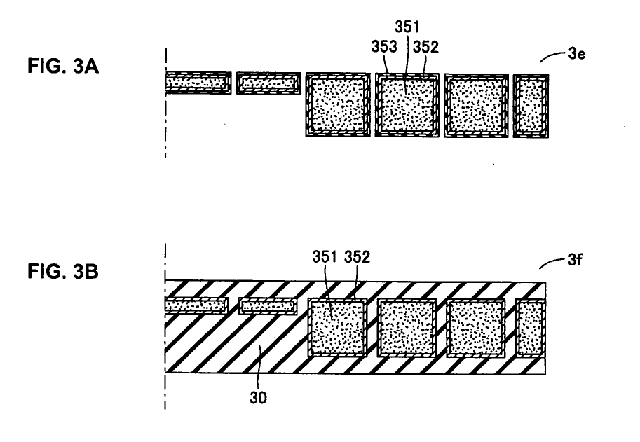

FIGS. 3A and 3B are sectional views showing another example of a radius part of an antenna member used in the plasma processing device according to one embodiment of the present invention. While the antenna member 3 shown in FIG. 2 is formed of the electrically conductive material such as copper, an antenna member 3e shown in FIG. 3A is formed by coating an electrically conductive material 352 on the surface of an insulating member 351 such as ceramics and covering it with an insulating member 353.

Since metal has high coefficient of thermal expansion, when the temperature rises, a dimension could be varied. Meanwhile, since the insulating member 351 has relatively small coefficient of thermal expansion, when the electrically conductive material 352 is coated on the surface of the insulating member 351, it can be used as a planar antenna member. In addition, when the insulating member 353 is coated on the surface of the electrically conductive material 352, abnormal discharge resistance is improved.

Furthermore, an antenna member 3f shown in FIG. 3B is formed by coating the electrically conductive material 352 on the surface of the insulating member 351 such as ceramics and covering its upper part and lower part with a dielectric material 30 instead of the insulating member 353.

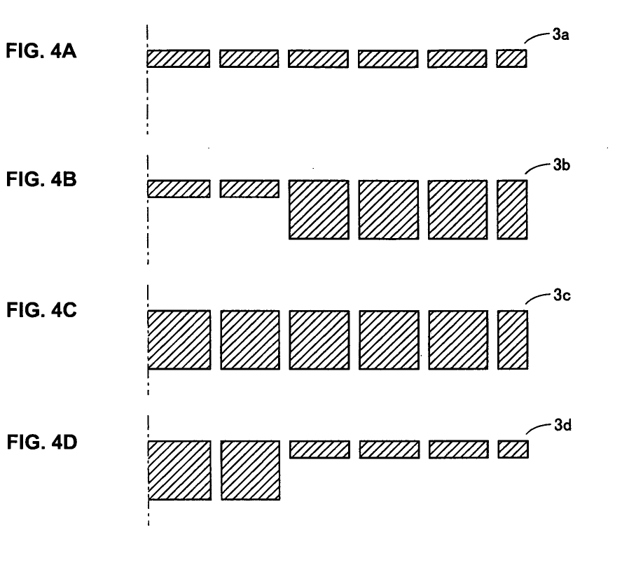

FIGS. 4A to 4D are sectional views showing radius parts of various kinds of antenna members having different thicknesses. Although a plurality of concentric ring-shaped slots are formed in each of antenna members 3a to 3d shown in FIGS. 4A to 4D, the thicknesses of them are differentiated.

More specifically, the antenna member 3a shown in FIG. 4A is thinly formed as a whole. The antenna member 3b shown in FIG. 4B, which is applied to one embodiment of the present invention, is formed such that its peripheral part is thick and its central part is thin. The antenna member 3c shown in FIG. 4C, which is applied to another embodiment of the present invention, is thickly formed as a whole in which its thickness is not less than λ/8 and more preferably not less than λ/4 of a guide wavelength. Here, when there are several ring-shaped slots, any slot can separate an inner conductor and an outer conductor, and a conductor inside the selected slot becomes the inner conductor and a conductor outside that slot becomes the outer conductor. The antenna member 3d shown in FIG. 4D is formed such that its peripheral part is thin and its central part is thick.

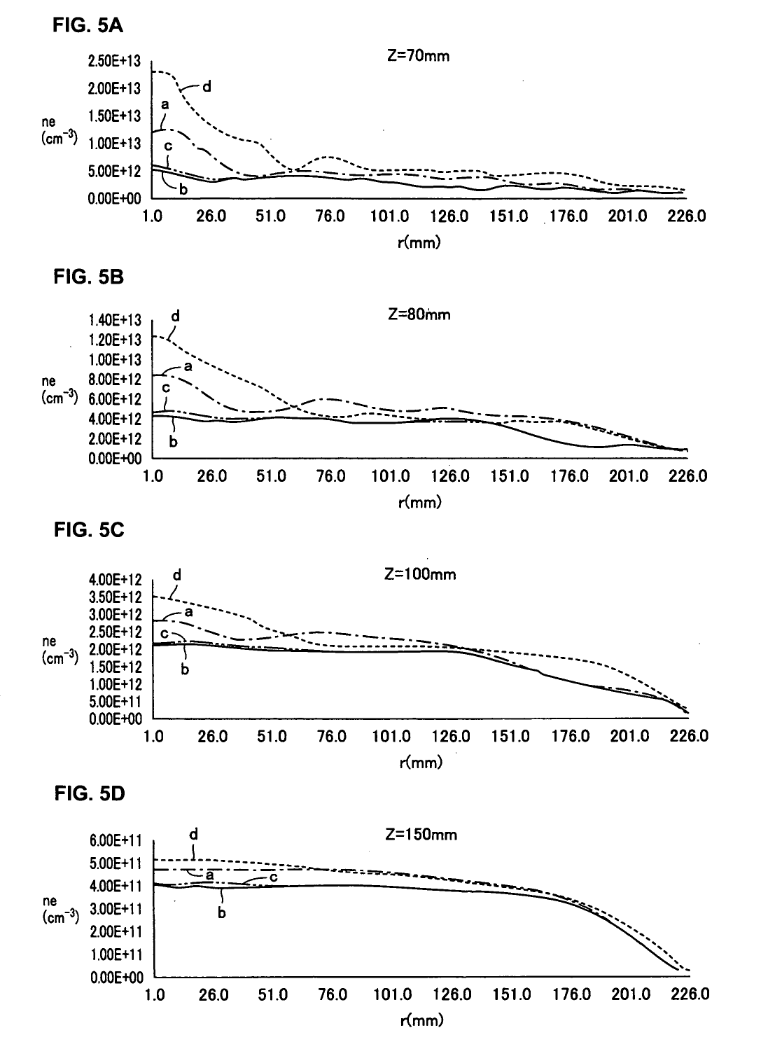

In the lower direction (Z direction) on the side of the processing space “S” of the antenna members 3a to 3d, when it is assumed that the upper surface of the antenna is Z=0,FIGS. 5A to 5D show electron density distributions at positions Z=70 mm, 80 mm, 100 mm, and 150 mm in which the vertical axis shows electron density “ne” (cm⁻³) and the horizontal axis shows a distance (r) in the radius direction. In addition, FIGS. 5A to 5D show the electron density distributions when the pressure in the processing space “S” is 0.5 Torr and an inputted power of the microwave is 3000 W.

In FIGS. 5A to 5D, a waveform “a” shows the electron distribution in the antenna member 3a shown in FIG. 4A, a waveform “b” shows the electron distribution in the antenna member 3b shown in FIG. 4B, a waveform “c” shows the electron distribution in the antenna member 3c shown in FIG. 4C, and a waveform “d” shows the electron distribution in the antenna member 3d shown in FIG. 4D.

As can be clear by comparing the waveforms shown in FIGS. 5A to 5D, according to the waveform “d” in the vicinity of Z=70 mm shown in FIG. 5A, the electron density in the vicinity of the center is high and largely different from that in the peripheral part. This is because the antenna member 3d in the vicinity of the center is thickly formed while the peripheral part thereof is thinly formed. According to the waveform “a”, although the electron density in the center is lower than that of the waveform “d” of the antenna member 3d, it is higher than that of its peripheral part. This is because the antenna member 3a is thickly formed as a whole. Meanwhile, according to the waveforms “b” and “c”, the difference in electron density between the center part and the peripheral part is small and a uniform electric field is provided. This is because the peripheral parts of the antenna members 3b and 3c are thickly formed.

In the vicinity of Z=80 mm shown in FIG. 5B, the waveforms “a” and “d” of the antenna members 3a and 3d have large difference in electron density distribution between the central part and the peripheral part, and the waveforms “b” and “c” of the antenna members 3b and 3c have small difference in electron density distribution between the central part and the peripheral part and implement uniform distribution. In the vicinity of Z=100 mm shown in FIG. 5C and in the vicinity of Z=150 mm shown in FIG. 5D, the longer the distance in the Z direction is, the lower the absolute value of the electron density of each of the waveforms “a” to “d” is.

According to the above characteristics, uniformity such that the electron density difference is about ±10%, for example within a range “r”=0 to 150 mm can be implemented in the antenna members 3a and 3d in the vicinity of Z=150 mm, in the antenna member 3b in the vicinity of Z=80 mm, and in the antenna member 3c in the vicinity of Z=100 mm. Therefore, it is found that in order to implement high-density and uniform plasma distribution, the antenna member 3b shown in FIG. 4B is most preferable.

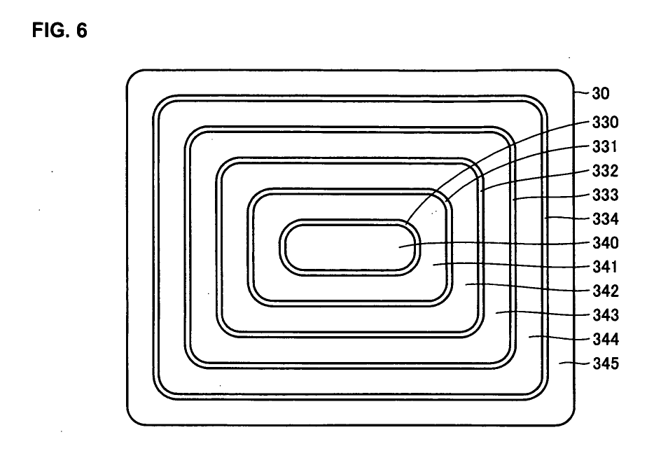

FIG. 6 is a view showing an antenna member according to another example. In this example, an antenna member 30 is formed into a rectangular configuration as a whole in which a plurality of slots 330 to 334 are formed as concentric coaxially rectangular closed grooves in the form of loops and it is separated into conductors 340 to 345 by these slots 330 to 334. In this example also, similar to the antenna member 3 shown in FIG. 1, the conductors 340 and 341 on the center side are relatively thin and the peripheral conductors 342 and 345 are relatively thick. The other conditions and the like are selected similar to FIG. 1.

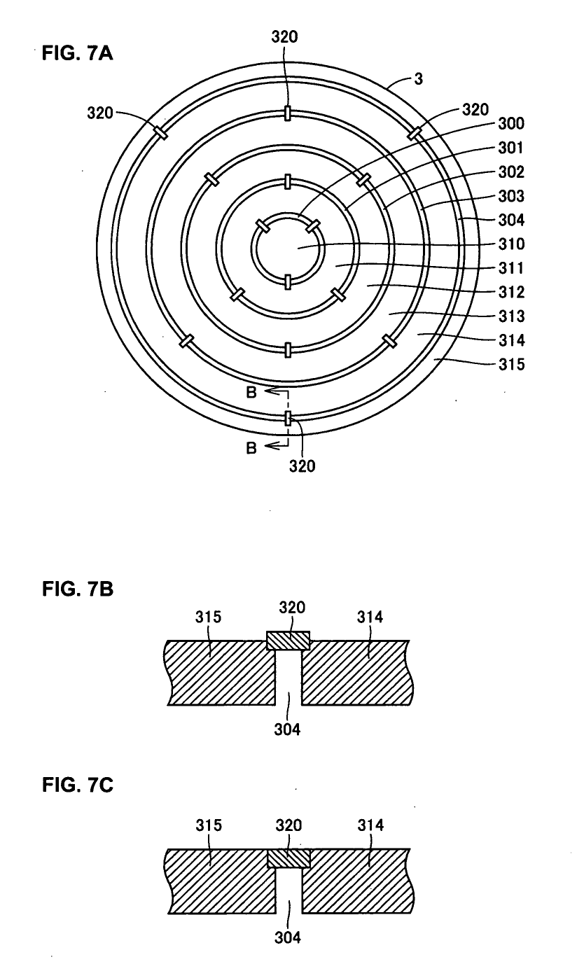

FIGS. 7A to 7C show an example in which conductors of the antenna member are connected by electric conductors, in which FIG. 7A is a plan view, FIG. 7B is a sectional view taken along line B-B in FIG. 7A, and FIG. 7C is a view showing an electric conductor in another example.

Since the conductors 310 to 315 are electrically separated by the slots 300 to 304 in the antenna member 3 shown in FIG. 1, there is a merit in which the microwave is not attenuated when passes through the slot. However, each of the conductors 310 to 315 is electrically charged and unnecessary abnormal discharge could be generated.

Thus, according to the example shown in FIG. 7A, the conductors 310 to 315 are electrically connected by electric conductors 320 serving as a connecting members to make them have the same potential, so that the unnecessary abnormal discharge is prevented from being generated.

As shown in FIG. 7B, the lower half of the electric conductor 320 in the height direction connects the conductors 314 and 315 and the upper half thereof projects from the surfaces of the conductors 314 and 315. Alternatively, as shown in FIG. 7C, the whole part of the electric conductor in the height direction may connect the conductors 314 and 315. That is, not all but a part of the slots 300 to 304 in the height direction provided between the conductors 310 to 315 may be crossed (bridged) by the electric conductors 320 and it is preferable that the thickness of the conductor 320 is as thin as possible.

In addition, the conductor 320 shown in FIG. 7 may be provided in the antenna member 30 shown in FIG. 6.

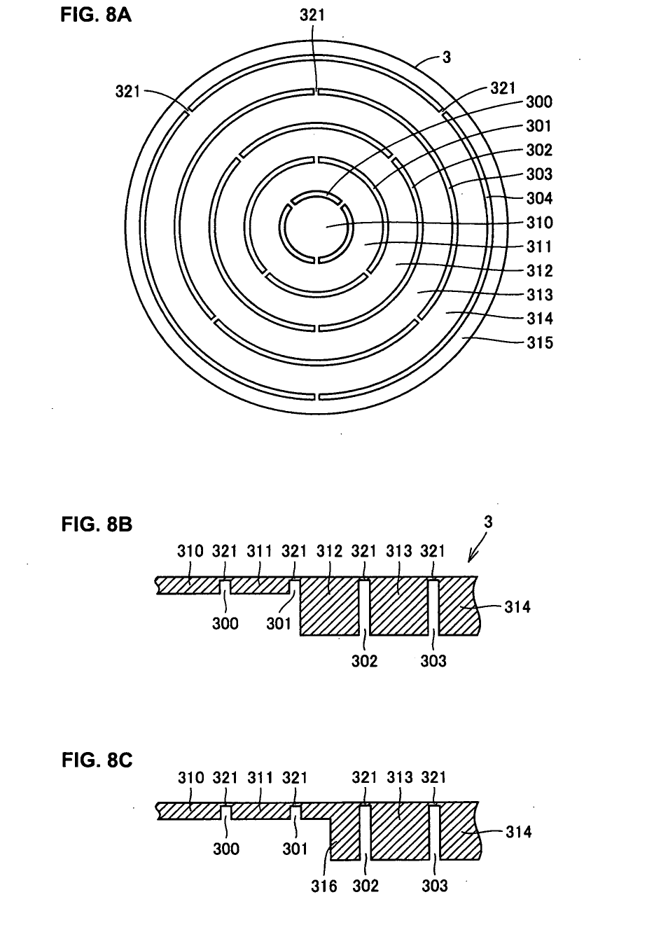

FIGS. 8A to 8C show an example in which a connecting part is formed across slots of an antenna member. FIG. 8A is a plan view showing the antenna member, FIG. 8B is an enlarged sectional view showing the connecting part, and FIG. 8C is a sectional view showing a connecting part in another example.

According to the example shown in FIG. 8A, in order to make uniform the potentials of conductors 311 to 315, a connecting part 321 as a connecting member is formed by remaining a part of the antenna member without penetrating that part. In this example also, unnecessary abnormal discharge is prevented from being generated in the conductors 310 to 315. In addition, the connecting part 321 may be applied to the antenna member 30 shown in FIG. 6.

Although the antenna member is separated into the thin conductor 311 and the thick conductor 312 by the slot 301 according to the example shown in FIG. 8B, the present invention is not limited to this. As shown in FIG. 8C, a conductor 316 having a stepped part comprising a thin part and a thick part in the height direction may be provided. That is, it is not necessary to provide the thin conductor and the thick conductor along the slot. In addition, inner conductors correspond to the conductors 310, 311 and 316 in FIG. 8C.

Although the embodiments of the present invention have been described with reference to the drawings in the above, the present invention is not limited to the above-illustrated embodiments. Various kinds of modifications and variations may be added to the illustrated embodiments within the same or equal scope of the present invention.

### INDUSTRIAL APPLICABILITY

According to the plasma processing device in the present invention, since a uniform electric field can be formed in the vicinity of the antenna member by supplying a microwave, and uniform high-density plasma can be generated over a plane in a processing space, it can be advantageously applied to plasma processing for a semiconductor wafer such as plasma CVD, etching, oxidizing, nitriding and the like.

What is claimed:

1. A plasma processing device comprising:
a processing vessel housing a table on which an object to be processed is set;
a microwave generator for generating a microwave;
a waveguide for guiding the microwave generated by said microwave generator to said processing vessel; and
a planar antenna member connected to said waveguide and arranged so as to be opposed to said table, characterized in that
said planar antenna member is separated into an inner conductor region and an outer conductor region by a substantially closed loop groove.

2. The plasma processing device according to claim 1, wherein a plurality of said loop grooves are provided and they are concentrically arranged.

3. The plasma processing device according to claim 1, wherein a plurality of said loop grooves are provided and they are concentrically arranged in the form of rectangles.

4. The plasma processing device according to claim 1, wherein said loop groove is a slot penetrating said planar antenna member in the thickness direction.

5. The plasma processing device according to claim 1, wherein said inner conductor region and said outer conductor region are connected by a connecting member crossing said loop groove.

6. The plasma processing device according to claim 5, wherein said connecting member connects said inner conductor region and said outer conductor region in said loop groove in the height direction.

7. The plasma processing device according to claim 1, wherein said planar antenna member has a peripheral part formed to be relatively thick and a central part formed to be relatively thin.

8. The plasma processing device according to claim 1, wherein said planar antenna member comprises:
a metal member constituting said inner conductor region and said outer conductor region separated by said loop groove; and
an insulating member covering said metal member.

9. The plasma processing device according to claim 1, wherein said planar antenna member comprises:
an insulating member separated by said loop groove; and
an electrically conductive member coated on the surface of said insulating member to constitute said inner conductor region and said outer conductor region separated by said loop groove.

10. The plasma processing device according to claim 7, wherein said inner conductor region is formed to be relatively thin and said outer conductor region is formed to be relatively thick along said loop groove.

11. The plasma processing device according to claim 7, wherein the inner conductor region adjacent to said loop groove comprises a stepped part in which a thin part and a thick part are formed in the thickness direction.

12. The plasma processing device according to claim 7, wherein a cooling path is formed at a part in said peripheral part formed to be thick.

13. The plasma processing device according to claim 1, wherein said planar antenna member has a thickness of λ/8 or more.
